(19) United States
(12) Patent Application Publication
(10) Pub. No.: US 2025/0385550 A1
(43) Pub. Date: Dec. 18, 2025

(54) DIFFERENTIAL VOLTAGE CAPACITOR SENSING AMPLIFIER FOR WIRELESS POWER

(71) Applicant: Renesas Electronics America Inc., Milpitas, CA (US)

(72) Inventors: Marco SAUTTO, Zurich (CH); Sercan IPEK, Seefeldstrasse (CH)

(73) Assignee: Renesas Electronics America Inc., Milpitas, CA (US)

(21) Appl. No.: 19/234,435

(22) Filed: Jun. 11, 2025

Related U.S. Application Data
(60) Provisional application No. 63/660,178, filed on Jun. 14, 2024.

(51) Int. Cl. H02J 50/12

(52) U.S. Cl. CPC H02J 50/12

(57) ABSTRACT

Systems and methods implementing an improved DVCS amplifier are described. The integrated circuit can include a controller. The integrated circuit can further include an amplifier configured to measure a common mode voltage across a capacitor of a switching converter. The integrated circuit can include a circuit configured to receive a differential input being provided to the amplifier. Based on the differential input, the circuit can further be configured to maintain the common mode voltage to regulate the amplifier within an operating range of the amplifier.

### CROSS-REFERENCE TO RELATED APPLICATION

The subject application claims the benefit of U.S. Provisional Application No. 63/660,178, filed on Jun. 14, 2024. The entire disclosure of U.S. Provisional Application No. 63/660,178 is incorporated by this reference.

### BACKGROUND

The present disclosure relates in general to apparatuses and methods for sensing current in coils of wireless power devices. Particularly, example systems that can implement an improved Differential Voltage Capacitor Sensing (DVCS) amplifier are described.

Wireless power systems can include a transmitter having a transmission coil and a receiver having a receiver coil. In an aspect, the transmitter may be connected to a structure including a wireless charging region. In response to a device including the receiver being placed on the charging region, or in proximity to the charging region, the transmission coil and the receiver coil can be inductively coupled with one another to form a transformer that can facilitate inductive transfer of alternating current (AC) power. The transfer of AC power, from the transmitter to the receiver, can facilitate charging of a battery of the device including the receiver.

### SUMMARY

In one embodiment, an integrated circuit that can implement an improved DVCS amplifier is generally described. The integrated circuit can include a controller. The integrated circuit can further include an amplifier configured to measure a common mode voltage across a capacitor of a switching converter. The integrated circuit can include a circuit configured to receive a differential input being provided to the amplifier. Based on the differential input, the circuit can further be configured to maintain the common mode voltage to regulate the amplifier within an operating range of the amplifier.

In one embodiment, a wireless power device that can implement an improved DVCS amplifier is generally described. The wireless power device can include a controller. The wireless power device can further include an amplifier configured to measure a common mode voltage across a capacitor of a switching converter. The wireless power device can further include a circuit configured to receive a differential input being provided to the amplifier. Based on the differential input, the circuit can further maintain the common mode voltage to regulate the amplifier within an operating range of the amplifier.

In one embodiment, a method that can implement an improved DVCS amplifier is generally described. The method can include receiving a differential input being provided to an amplifier of a wireless power device. Based on the differential input, the method can further include maintaining a common mode voltage being outputted by the amplifier to regulate the amplifier within an operating range of the amplifier.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing an example system that can implement an improved DVCS amplifier in one embodiment.

FIG. 2 is a diagram showing details of the example system shown in FIG. 1 in one embodiment.

FIG. 3 is a waveform diagram illustrating another example system that can implement an improved DVCS amplifier in one embodiment.

FIG. 4 is a flowchart diagram illustrating an example implementation of an improved DVCS amplifier in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

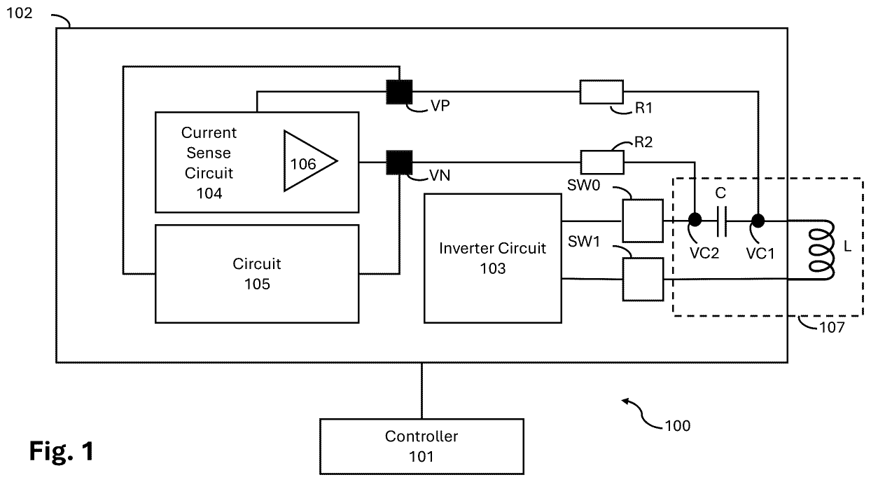

FIG. 1 is a diagram showing an example system that can implement improved DVCS in one embodiment. System 100 can include a controller 101 and a power device 102, such as a transmitter or receiver.

Controller 101 can be configured to control and operate power device 102. Controller 101 can include, for example, a processor, central processing unit (CPU), field-programmable gate array (FPGA) or any other circuitry that is configured to control and operate power device 102. While described as a CPU in illustrative embodiments, controller 101 is not limited to a CPU in these embodiments and may comprise any other circuitry that is configured to control and operate power device 102 in system 100.

Power device 102 can be a semiconductor device connected to an external inductor L. Power device 102 can comprise of a capacitor C, a switching node SW0, a switching node SW1, an inverter circuit 103, current sense circuit 104 and a circuit 105.

In an embodiment where power device 102 operates as a wireless power transmitter, power device 102 can include a resonant circuit 107 comprising of an inductor L and a capacitor C. In another example embodiment, power device 102 can operate as a wireless power receiver.

Power device 102 can include switching node SW0 and switching node SW1 which can be driven by field-effect transistors (FETs) such as metal oxide semiconductor field effect transistors (MOSFETs). In other embodiments, Switching node SW0 and switching node SW1 can be connected to diodes or insulated-gate bipolar transistors (IGBTs). Power device 102 can further include a first resistor R1 and a second resistor R2. The resistor R1 can be connected in series between a node VC1 and node VP and the resistor R2 can be connected between node VC2 and node VN.

Controller 101 can be configured to operate the inverter circuit 103 to drive switching node SW0 and switching node SW1 in an alternating fashion, thereby generating a high-frequency alternating current (AC) across capacitor C and inductor L of resonant circuit 107. This high-frequency signal creates an oscillating electromagnetic field for wireless power transmission for a power device 102 operating as a receiver to receive the signal. The inverter circuit 103 can be configured to generate Pulse Width Modulation (PWM) signals to pull up or down the switching node SW0 and switching node SW1 alternately. In one phase, the pull up of switching node SW0 and pull down of switching node SW1 can charge the capacitor C to high positive voltage (e.g., 50 V). In the next phase, the pull up of switching node SW0 and pull down of switching node SW1 can discharge the voltage of capacitor C to a high negative voltage (e.g., −50 V). The rapid alternate switching of switching nodes SW0 and SW1 thereby generates the high-frequency AC across the capacitor C and the inductor L of resonant circuit 107.

The voltage observed across capacitor C includes both differential-mode and common-mode components. The differential-mode voltage is defined as the voltage difference between nodes VC1 and VC2 of capacitor C. This signal contains information related to the current and resonant behavior of the circuit. In contrast, the common-mode voltage is the average of the voltages at node VC1 and node VC2 and results from large voltage swings due to the switching action of switching node SW0 and switching node SW1.

In conventional systems and configurations, a sense resistor can be placed in series with capacitor C and inductor L. An amplifier can be used to measure the voltage drop across this resistor because the measured voltage is directly proportional to the current flowing through the resistor. However, in this configuration, the differential-mode voltage across the sense resistor is very small, while the common-mode voltage present in the circuit can be extremely large. This makes it challenging to design or use an amplifier capable of accurately extracting the small differential signal without being affected by large common-mode swings.

Instead, in some conventional systems, the voltage across capacitor C can be measured. This voltage is proportional to the integral of the current in the resonant circuit 107. For example, as shown in the embodiment of FIG. 1, power device 102 can include a current sense circuit 104 comprising of an amplifier 106. In one embodiment, amplifier 106 can be implemented as a differential voltage capacitor sensing (DVCS) amplifier for sensing voltage and controlling output power if system 100 is a part of a wireless power transmitter. The sensing of the voltage ensures a wireless power receiver to receive the correct amount of power. The amplifier 106 can be, for example, a fully differential operational amplifier. The first resistor R1 and the second resistor R2 of power device 102 can each have relatively large resistance values (e.g., 200 kΩ). Amplifier 106 is configured to measure the differential-mode across nodes VC1 and VC2. The first and second resistors are matched to improve common-mode rejection and enables the use of a low-voltage differential amplifier input stage even in the presence of large common-mode signals.

However, due to the resonant characteristics of resonant circuit 107, even with the first and second resistors, the differential-mode voltage across capacitor C can still reach values much higher than the input voltage (e.g., up to 100 V), and the common-mode voltage can swing over an unexpectedly wide range. Moreover, the differential-mode and common-mode voltage signals can vary independently and are not necessarily proportional. Previous techniques attempted to address this issue by employing switched resistor networks, where a switched resistor was connected between node VP and ground and another switched resistor was connected between node VN and ground to help maintain the common-mode voltage within the amplifier's input range.

To be described in more detail below, the embodiment described in FIG. 1 includes a circuit 105. The circuit 105 can be connected in parallel to the amplifier inputs at nodes VP and VN, and configured as a common-mode control loop. Circuit 105 enables the system to accommodate a wider common-mode voltage swing while maintaining high common-mode rejection, allowing amplifier 106 and associated components within system 100 to operate within low-voltage ranges safely and reliably.

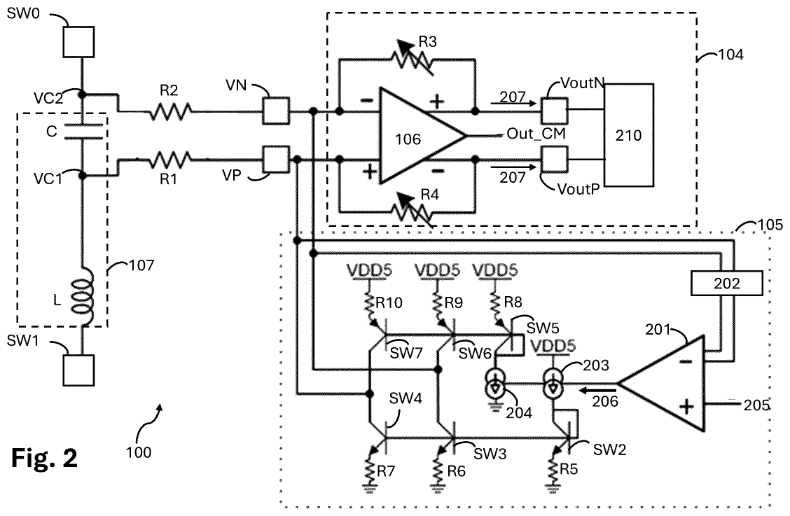

FIG. 2 is a diagram showing details of the example system shown in FIG. 1 in one embodiment. Descriptions of FIG. 2 may reference components shown in FIG. 1. In the example embodiment shown in FIG. 2, current sense circuit 104 can further comprise of a first variable resistor R3, a second variable resistor R4, and an Analog to Digital Converter (ADC) 210. The amplifier 106 in current sense circuit 104 is configured to receive inputs at node VN and node VP. The inverting input of the amplifier 106 can be connected in series to the VN node and the non-inverting input of the amplifier 106 can be connected in series to the VP node. A first variable resistor R3 can be connected in parallel to the amplifier at the inverting input of the amplifier 106 and a second variable resistor R4 can be connected in parallel to the amplifier at the non-inverting input of the amplifier 106. The first variable resistor R3 and the second variable resistor R4 can be configured as feedback resistors for the amplifier 106. These feedback resistors help maintain balance in the amplifier 106, allowing the internal control loop formed by amplifier 106 and feedback resistors R3, R4 to keep the differential voltage at the inputs of amplifier 106 near zero under steady-state conditions. The amplifier 106 can continuously adjusts its output differential voltage signals 207 to correct any small input differences.

Amplifier 106 can be configured to output the differential voltage signals 207 at nodes VoutP and VoutN, centered around the common-mode voltage as Out_CM. The output common-mode voltage Out_CM can be provided by controller 101. The differential output signals VoutP, VoutN from amplifier 106 can be provided to the ADC 210 for digitization. ADC 210 can convert the differential outputs VoutP, VoutN into digital values, where the digital signals can be further processed, for example, by controller 101 to determine the voltage across capacitor C. In one embodiment, the controller 101 can determine a derivative of the digital signals, outputted by ADC 210, over time to estimate the current flowing through the capacitor C, since the current through a capacitor is proportional to the derivative of its voltage. Given the series relationship between capacitor C and inductor L in the resonant circuit 107, the capacitor current (e.g., current flowing through C) is equivalent to the inductor current (e.g., current flowing through L). Based on the capacitor current over time, the system 100 can determine the root-mean-square (RMS) value of the inductor current.

In another example embodiment, the fully differential amplifier 106 may be implemented as a differential attenuator. Rather than amplifying the differential signals output from nodes VC1 and VC2, amplifier 106, when implemented as the differential attenuator, is configured to reduce or scale down the voltage across nodes VC1 and VC2, thereby producing a differential output signal that remains within the input voltage range of the ADC 210.

In the example embodiment shown in FIG. 2, circuit 105 can be connected in parallel to the inputs of the amplifier 106. A first input of circuit 105 can be connected to the node VN and a second input of circuit 105 can be connected to the node VP. Circuit 105 can comprise of an operational amplifier 201, a maximum selector 202, a first current source 203, a second current source 204, transistors SW2, SW3, SW4, SW5, SW6, SW7, and resistors R5, R6, R7, R8, R9 and R10. Transistors SW2, SW3, SW4, SW5, SW6, SW7 can be bipolar junction transistors (BJT). In another embodiment, the transistors SW2, SW3, SW4, SW5, SW6, SW7 can be MOSFETs, or degenerated MOSFETs, or a mix of MOSFETs and BJTs.

Circuit 105 can be configured as a degenerated push-pull current mirror structure comprising transistors SW2, SW3, SW4, SW5, SW6, SW7 and resistors R5, R6, R7, R8, R9 and R10. On the source side of the push-pull stage, transistor SW2 is configured to be a reference transistor for transistors SW3 and SW4. These transistors, together with resistors R5, R6, and R7, form a degenerated current mirror that sources current to nodes VP and VN. On the sink side, transistor SW5 is configured to be the reference transistor for transistors SW6 and SW7. These transistors, together with resistors R8, R9, and R10, form a degenerated current mirror that sinks current to nodes VP and VN. In one example embodiment, the source side can comprise of NPN BJTs and the sink side can comprise of PNP BJTs. In another example embodiment, the source side can comprise of PNP BJTs and the sink side can comprise of NPN BJTs. In another example embodiment, both the source side and sink side can comprise of only NPN BJTs or only PNP BJTs. The resistors in these paths serve as degeneration resistors, which improve current mirror linearity and stabilize current flow. This degenerated push-pull arrangement allows circuit 105 to dynamically source or sink equal current into both VP and VN in a controlled, symmetric manner. Because the same current is applied to both input nodes simultaneously, the circuit affects only the common-mode voltage without disturbing the differential signal being input into amplifier 106.

Maximum selector 202 can be configured to receive the voltages at node VN and node VP. During normal operation of amplifier 106, the differential voltage between VP and VN should remain close to zero, meaning the voltages at VP and VN should be approximately equal. Under these balanced conditions, maximum selector 202 may randomly select either VP or VN for output to operational amplifier 201. However, when amplifier 106 becomes unbalanced and a significant voltage difference arises between VP and VN, maximum selector 202 is configured to select the higher of the two voltages and output it to operational amplifier 201. This ensures that the operational amplifier 201 operates based on the maximum common-mode deviation.

Operational amplifier 201 can be, for example, a class AB transconductance amplifier. Operational amplifier 201 can be configured to receive the output of maximum selector 202 at its inverting input and the reference voltage 205 at its non-inverting input. The system 100 is regulated with respect to reference voltage 205, which may be preset, for example, at 0.9 V. Operational amplifier 201 outputs an output signal 206 based on the difference between the reference voltage and the output of the maximum selector 202. This output signal 206 is provided to two current sources. A first current source 203 connected to the sink (pull) side of the push-pull circuit and a second current source 204 connected to the source (push) side of the push-pull circuit.

Under balanced conditions, i.e., when the common-mode voltage output of maximum selector 202 equals the reference voltage 205, the first current source 203 and the second current source 204 output equal current values. Thereby setting the quiescent current of circuit 105. When the common-mode voltage deviates from the reference voltage 205, the first current source 203 and second current source 204 can be configured to output difference current values. Depending on the imbalance, for example, if the common-mode voltage output of maximum selector 202 is greater than the reference voltage 205, then the first current source 203 can generate a current value greater than the current generated by the second current source 204. If the common-mode voltage output of maximum selector 202 is less than the reference voltage 205, then the first current source 203 can generate a current value less than the current generated by the second current source 204. In another embodiment, if the common-mode voltage output of maximum selector 202 is greater than the reference voltage 205, then the second current source 204 can generate a current value less than the current generated by the first current source 203. If the common-mode voltage output of maximum selector 202 is less than the reference voltage 205, then the second current source 204 can generate a current value greater than the current generated by the first current source 203.

More specifically, when operational amplifier 201 detects that the common-mode voltage (as selected by maximum selector 202) exceeds the reference voltage 205 (i.e., signal 206=HIGH), second current source 204 activates the source side of the push-pull circuit. This causes switches SW5, SW6, and SW7 to conduct in coordination with resistors R8, R9, and R10, thereby drawing current symmetrically from nodes VP and VN and reducing the common-mode voltage. Conversely, when the common-mode voltage falls below the reference voltage (i.e., signal 206=LOW), first current source 203 activates the sink side of the circuit. Switches SW2, SW3, and SW4 then conduct in coordination with resistors R5, R6, and R7, sinking current symmetrically into nodes VP and VN and increasing the common-mode voltage. This regulation loop stabilizes the common-mode voltage presented to amplifier 106, ensuring that its inputs remain within the amplifier 106 operating range. Because circuit 105 utilizes matched current mirrors and degeneration resistors implemented on silicon, it can precisely source or sink equal current to both inputs, preserving symmetry and improving rejection of common-mode components. As a result, amplifier 106 can focus exclusively on accurately amplifying the differential-mode signal, even in the presence of large and varying common-mode voltages, enhancing signal integrity and enabling robust current sensing in high-voltage environments.

In another example embodiment, ADC 210 can be implemented as a fast sampling analog-to-digital converter (ADC). A fast sampling ADC is configured to operate at a higher frequency, for example at 4 Mhz, which can enable higher-resolution time-domain analysis of the differential signal and allow finer granularity in estimating dynamic current waveforms in the resonant circuit. However, this approach may introduce challenges related to aliasing of higher-order harmonics present in the system. Such harmonics can originate from multiple sources, including in-channel amplitude-shift keying (ASK) communication, and noise or ripple from the input voltage. If not properly filtered or managed, these high-frequency components can distort the measurement of the intended signal.

Therefore, to mitigate aliasing caused by high-frequency harmonic content when using a fast sampling ADC, an Nth-order low-pass filter can be placed within the DVCS circuit, between the amplifier 106 and the ADC 210. This filter is configured with a specific corner frequency selected to attenuate undesired high-frequency components while preserving the frequency range of interest. In one embodiment, a separate low-pass filter is provided for each ADC input to minimize timing mismatches and reduce delays related to filter settling. The filter may be bypassed entirely in scenarios where full-bandwidth analog signals are required downstream, such as when outputting directly to external analog circuits. In other embodiments, different filter configurations can be employed depending on the application—for example, to support specific demodulation tasks such as ASK communication or foreign object detection (FOD). These filter configurations can help reduce the digital data processing burden by suppressing unnecessary frequency components at the analog front end, saving power, area, and system cost. In still other embodiments, the low-pass filter may be programmable, allowing its characteristics to be dynamically adjusted to match the system's filtering needs, particularly when used with variable-speed ADCs or time-varying signal conditions.

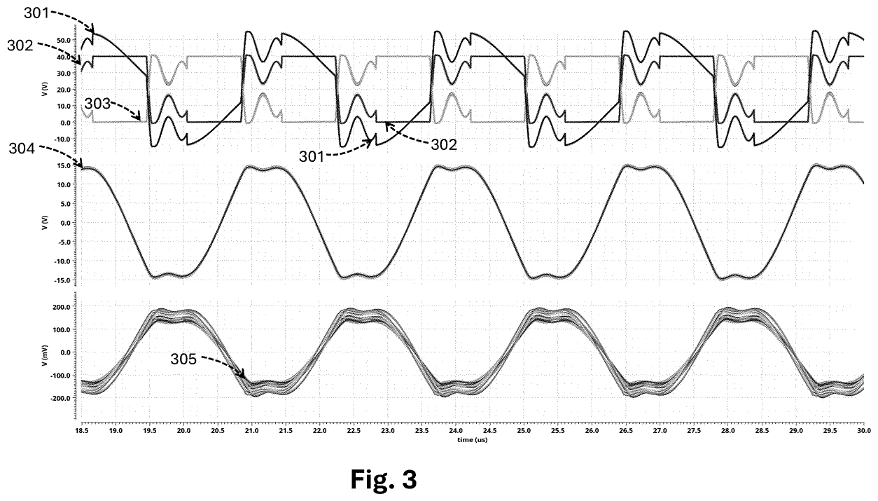

FIG. 3 is a diagram showing waveforms of an example implementation of an improved DVCS amplifier. Descriptions of FIG. 3 can reference components that are shown in FIG. 1 to FIG. 3. Waveform 301 represents the voltage at the node between inductor L and capacitor C, which corresponds to the common-mode voltage observed at the input of amplifier 106. As shown, this node experiences significant voltage swings, ranging from over 50 V to below −10 V. This large common-mode variation is due to the resonant nature of the circuit and the high-voltage switching activity of switching nodes SW0 and SW1.

Waveforms 302 and 303 show the switching node voltages at SW0 and SW1, respectively. Compared to waveform 301, the voltages at SW0 and SW1 distinctly exhibit the switching transitions from 40 V to 0 V. This further highlights that the node between the inductor and capacitor (waveform 301) experiences even greater voltage swings than the switching nodes themselves, showing the challenge of extracting a small differential signal in the presence of large and independently varying common-mode voltage components.

Waveform 304 illustrates the differential-mode voltage at the input of amplifier 106. The differential-mode voltage retains a relatively large swing, with an absolute peak voltage of approximately 15 V.

Waveform 305 shows the differential-mode voltage output from amplifier 106. Here, the effects of common-mode rejection caused by the circuit 105 can be observed. The waveform 305 is a well-matched and inverted version of the input differential-mode voltage shown in waveform 304, but significantly scaled down in magnitude from the attenuation of the amplifier 106. The absolute peak voltage at the output is approximately 200 mV, indicating successful attenuation and conditioning of the signal for further processing, such as analog-to-digital conversion. This demonstrates that amplifier 106, assisted by circuit 105, is able to reject the large common-mode component, maintain signal integrity, and output a low-voltage, differential signal suitable for precision measurement, monitoring, or digital conversion.

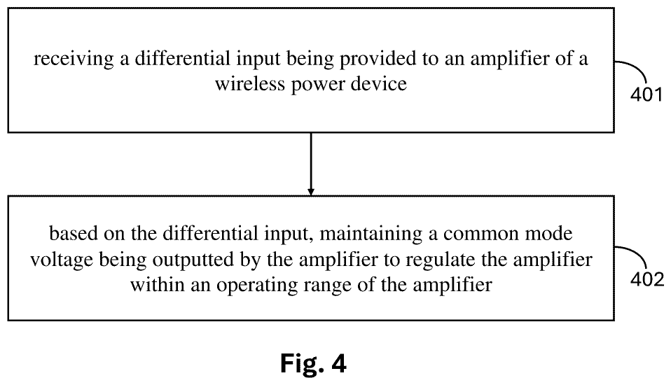

FIG. 4 is a flowchart of an example process that can implement an improved DVCS amplifier in one embodiment. A process 400 in FIG. 4 may be implemented using, for example, system 100 discussed above. Process 400 can include one or more operations, actions, or functions as illustrated by one or more of blocks 401 and/or 402. Although illustrated as discrete blocks, various blocks may be divided into additional blocks, combined into fewer blocks, eliminated, performed in different order, or performed in parallel, depending on the desired implementation.

Process 400 can be performed by a controller (controller 101 described herein). Process 400 can begin at block 401. At block 401, the controller can receive a differential input being provided to an amplifier of a wireless power device. The process can continue from block 401 to block 402. At block 402, the controller can, based on the differential input, maintain a common mode voltage being outputted by the amplifier to regulate the amplifier within an operating range of the amplifier.

In one embodiment, the differential input comprises a first voltage and a second voltage. The controller can further select the higher voltage among the first voltage and the second voltage. The controller can further maintain the common mode voltage based on the higher voltage. In another embodiment, the controller can compare one input of the differential input with a reference voltage and output a comparison result to operate one of a first current source and a second current source. In another embodiment, the controller can generate equal current by the first current source and second current source, in response to the comparison result being equal. The controller can further generate different current values by the first current source and second current source, in response to the comparison result not being equal. In another embodiment, the differential input comprises a first voltage and a second voltage. The controller can randomly select one of the first voltage and the second voltage. The controller can further maintain the common mode voltage based on the selected voltage. In another embodiment, generating current by the first current source and second current source further comprises controlling a first set of transistors connected to the first current source and a second set of transistors connected to the second current source.

### Examples

Example 1: An integrated circuit comprising: a controller; an amplifier configured to measure a common mode voltage across a capacitor of a switching converter; and a circuit configured to: receive a differential input being provided to the amplifier; and based on the differential input, maintain the common mode voltage to regulate the amplifier within an operating range of the amplifier.

Example 2: The integrated circuit of example 1, wherein: the differential input comprises a first voltage and a second voltage; the circuit comprises a selector configured to select a higher voltage among the first voltage and the second voltage; and the circuit is configured to maintain the common mode voltage based on the higher voltage.

Example 3: The integrated circuit of any one of examples 1 and 2, wherein the circuit comprises a sink path and a source path.

Example 4: The integrated circuit of any one of examples 1 to 3, wherein the sink path comprises a first current source and a first set of transistors, and the source path comprises a second current source and a second set of transistors.

Example 5: The integrated circuit of any one of examples 1 to 4, wherein the circuit comprises an operational amplifier configured to: compare a voltage among the differential input with a reference voltage; and outputs a comparison result to operate the first and second current source based on the comparison result.

Example 6: The integrated circuit of any one of examples 1 to 5, wherein: the first current source and second current source generate equal current in response to the comparison result being equal; and the first current source and second current source generate different current values in response to the comparison result not being equal.

Example 7: The integrated circuit of any one of examples 1 to 6, wherein the controller, the amplifier and the circuit are parts of a wireless power transmitter or a wireless power receiver.

Example 8: A wireless power device comprising: a controller; an amplifier configured to measure a common mode voltage across a capacitor of a switching converter; and a circuit configured to: receive a differential input being provided to the amplifier; and based on the differential input, maintain the common mode voltage to regulate the amplifier within an operating range of the amplifier.

Example 9: The wireless power device of claim 8, wherein: the differential input comprises a first voltage and a second voltage; the circuit comprises a selector configured to select a higher voltage among the first voltage and the second voltage; and the circuit is configured to maintain the common mode voltage based on the higher voltage.

Example 10: The wireless power device of any one of examples 8 to 9, wherein the circuit comprises a sink path and a source path.

Example 11: The wireless power device of any one of examples 8 to 10, wherein the sink path comprises a first current source and a first set of transistors, and the source path comprises a second current source and a second set of transistors.

Example 12: The wireless power device of any one of examples 8 to 11, wherein the circuit comprises an operational amplifier configured to compare a voltage among the differential input with a reference voltage and outputs a comparison result to operate one of the sink path and the source path.

Example 13: The wireless power device of any one of examples 8 to 12, wherein: the first current source and second current source generate equal current in response to the comparison result being equal; and the first current source and second current source generate different current values in response to the comparison result not being equal.

Example 14: The wireless power device of any one of examples 8 to 13, wherein the controller, the amplifier and the circuit are parts of a wireless power transmitter or a wireless power receiver.

Example 15: A method comprising: receiving a differential input being provided to an amplifier of a wireless power device; and based on the differential input, maintaining a common mode voltage being outputted by the amplifier to regulate the amplifier within an operating range of the amplifier.

Example 16: The method of example 15, wherein: the differential input comprising a first voltage and a second voltage; the method further comprises: selecting the higher voltage among the first voltage and the second voltage; and maintaining the common mode voltage based on the higher voltage.

Example 17: The method of any one of examples 15 to 16, further comprising: comparing one input of the differential input with a reference voltage and outputting a comparison result to operate one of a first current source and a second current source.

Example 18: The method of any one of examples 15 to 17, further comprising: generating equal current by the first current source and second current source, in response to the comparison result being equal; and generating different current values by the first current source and second current source, in response to the comparison result not being equal.

Example 19: The method of any one of examples 15 to 18, wherein: the differential input comprises a first voltage and a second voltage; the method further comprises: randomly selecting one of the first voltage and the second voltage; and maintaining the common mode voltage based on the selected voltage.

Example 20: The method of any one of examples 15 to 19, wherein generating current by the first current source and second current source further comprises: controlling a first set of transistors connected to the first current source and a second set of transistors connected to the second current source.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An integrated circuit comprising:
a controller;
an amplifier configured to measure a common mode voltage across a capacitor of a switching converter; and
a circuit configured to:
receive a differential input being provided to the amplifier; and
based on the differential input, maintain the common mode voltage to regulate the amplifier within an operating range of the amplifier.

2. The integrated circuit of claim 1, wherein:
the differential input comprises a first voltage and a second voltage;
the circuit comprises a selector configured to select a higher voltage among the first voltage and the second voltage; and
the circuit is configured to maintain the common mode voltage based on the higher voltage.

3. The integrated circuit of claim 1, wherein the circuit comprises a sink path and a source path.

4. The integrated circuit of claim 3, wherein the sink path comprises a first current source and a first set of transistors, and the source path comprises a second current source and a second set of transistors.

5. The integrated circuit of claim 4, wherein the circuit comprises an operational amplifier configured to:
compare a voltage among the differential input with a reference voltage; and
outputs a comparison result to operate the first and second current source based on the comparison result.

6. The integrated circuit of claim 5, wherein:
the first current source and second current source generate equal current in response to the comparison result being equal; and
the first current source and second current source generate different current values in response to the comparison result not being equal.

7. The integrated circuit of claim 1, wherein the controller, the amplifier and the circuit are parts of a wireless power transmitter or a wireless power receiver.

8. A wireless power device comprising:
a controller;
an amplifier configured to measure a common mode voltage across a capacitor of a switching converter; and
a circuit configured to:
receive a differential input being provided to the amplifier; and
based on the differential input, maintain the common mode voltage to regulate the amplifier within an operating range of the amplifier.

9. The wireless power device of claim 8, wherein:
the differential input comprises a first voltage and a second voltage;
the circuit comprises a selector configured to select a higher voltage among the first voltage and the second voltage; and
the circuit is configured to maintain the common mode voltage based on the higher voltage.

10. The wireless power device of claim 8, wherein the circuit comprises a sink path and a source path.

11. The wireless power device of claim 10, wherein the sink path comprises a first current source and a first set of transistors, and the source path comprises a second current source and a second set of transistors.

12. The wireless power device of claim 11, wherein the circuit comprises an operational amplifier configured to compare a voltage among the differential input with a reference voltage and outputs a comparison result to operate one of the sink path and the source path.

13. The wireless power device of claim 12, wherein:
the first current source and second current source generate equal current in response to the comparison result being equal; and
the first current source and second current source generate different current values in response to the comparison result not being equal.

14. The wireless power device of claim 8, wherein the controller, the amplifier and the circuit are parts of a wireless power transmitter or a wireless power receiver.

15. A method comprising:
receiving a differential input being provided to an amplifier of a wireless power device; and
based on the differential input, maintaining a common mode voltage being outputted by the amplifier to regulate the amplifier within an operating range of the amplifier.

16. The method of claim 15, wherein:
the differential input comprising a first voltage and a second voltage;
the method further comprises:
selecting the higher voltage among the first voltage and the second voltage; and
maintaining the common mode voltage based on the higher voltage.

17. The method of claim 15, further comprising:
comparing one input of the differential input with a reference voltage and outputting a comparison result to operate one of a first current source and a second current source.

18. The method of claim 17, further comprising:
generating equal current by the first current source and second current source, in response to the comparison result being equal; and
generating different current values by the first current source and second current source, in response to the comparison result not being equal.

19. The method of claim 16, wherein:
the differential input comprises a first voltage and a second voltage; and
the method further comprises:
randomly selecting one of the first voltage and the second voltage; and
maintaining the common mode voltage based on the selected one of the first voltage and the second voltage.

20. The method of claim 18, wherein generating current by the first current source and second current source further comprises:
controlling a first set of transistors connected to the first current source and a second set of transistors connected to the second current source.
